(19) United States
(12) Patent Application Publication
(10) Pub. No.: US 2015/0058692 A1
(43) Pub. Date: Feb. 26, 2015

(54) LOW-DENSITY PARITY-CHECK DECODING METHOD AND LOW-DENSITY PARITY-CHECK DECODER USING THE SAME

(71) Applicant: Samsung Electronics Co., Ltd., Suwon-Si (KR)

(72) Inventors: Amir BENNATAN, Raanana (IL); Avner DOR, Kfar Saba (IL); Moshe TWITTO, Givat Shemuel (IL); Guy GABSO, Ramat Gan (IL); Yoav SHERESHEVSKI, Tel-Aviv (IL); Uri BEITLER, Ramat Gan (IL); Jun-jin KONG, Yongin-si (KR); Beom-Kyu SHIN, Seongnam-si (KR)

(21) Appl. No.: 14/334,947

(22) Filed: Jul. 18, 2014

(30) Foreign Application Priority Data
Aug. 26, 2013 (KR) 10-2013-0101274

(51) Int. Cl. H03M 13/11

(52) U.S. Cl. CPC H03M 13/1117
USPC 714/752

(57) ABSTRACT

A low-density parity-check (LDPC) decoding method includes exchanging messages between check nodes and variable nodes based on scheduling information representing an order of exchanging messages between the check nodes and the variable nodes for an LDPC decoding, and performing the LDPC decoding based on the exchanged messages, wherein the scheduling information is determined by manipulating at least one of an order of the check nodes and an order of the variable nodes in an LDPC bipartite graph.

### CROSS-REFERENCE TO RELATED APPLICATIONS

This application claims the benefit of Korean Patent Application No. 10-2013-0101274, filed on Aug. 26, 2013, under 35 U.S.C. §119 in the Korean Intellectual Property Office, the disclosure of which is incorporated herein in its entirety by reference.

### BACKGROUND

Inventive concepts relate to a decoding method and/or a decoding apparatus.

In a field of semiconductor memory, errors generated due to noise may be corrected by using a coding and decoding technology based on error correction codes. Among the error correction codes, a low-density parity-check code (LDPC) is an error correction code using a probability-based repeated calculation.

### SUMMARY

Some inventive concepts provide a low density parity check (LDPC) decoding method for improving memory access scheduling in a decoding process.

Some inventive concepts provide an LDPC decoder performing an LDPC decoding based on an efficient memory access scheduling.

According to an example embodiment of inventive concepts, there is provided a low density parity check (LDPC) decoding method, the method including exchanging messages between check nodes and variable nodes based on scheduling information representing an order of exchanging messages between the check nodes and the variable nodes for an LDPC decoding and performing the LDPC decoding based on the exchanged messages, wherein the scheduling information is determined by manipulating at least one of an order of the check nodes and an order of the variable nodes in an LDPC bipartite graph.

The order of the check nodes is manipulated and the manipulation of the order of the check nodes may be performed by exchanging numbers of the check nodes in a serial-check list according to the LDPC bipartite graph.

The order of the variable nodes is manipulated and the manipulation of the order of the variable nodes may be performed by reordering the variable nodes adjacent to each check node row in the serial-check list according to the LDPC bipartite graph.

After performing the manipulation of the order of the check nodes by exchanging the numbers of the check nodes in the serial-check list according to the LDPC bipartite graph, the scheduling information may be obtained by reordering the variable nodes adjacent to each check node in a serial-check list in which the order of the check nodes is manipulated.

The scheduling information may include information about memory-access processing order based on the order of exchanging the messages between the check nodes and the variable nodes.

The scheduling information prevents memory-access collisions in memory storing states of the variable nodes during the exchanging.

The scheduling information prevents read-before-write violations during the exchanging.

The scheduling information prevents memory-access collisions and read-before-write violations in memory storing states of the variable nodes during the exchanging.

The scheduling information may include information about a block-serial-check scheduling, and the block-serial-check scheduling permitting states of a plurality of variable nodes in the same block are accessed in parallel in one clock cycle.

The scheduling information may be determined by manipulating the order of the check nodes and the order of the variable nodes in the LDPC bipartite graph.

The states of the variable nodes may be stored separately in a plurality of memory sectors that are partitioned.

The scheduling information may be LDPC schedule table information including a serial-check list and a serial-variable list for each check node, wherein the LDPC schedule table information may be found by repeatedly performing a process of exchanging numbers of the check nodes in the serial-check list and a process of reordering the variable nodes in the serial-variable list of each check node i.

According to an example embodiment of inventive concepts, there is provided a low density parity check (LDPC) decoder including a first memory configured to store states of variable nodes in an LDPC bipartite graph, a second memory configured to store states of check nodes in the LDPC bipartite graph, a logic device module connected to the first memory and the second memory to perform calculations for exchanging messages between the check nodes and the variable nodes and a control device configured to control the logic device module to perform the message exchanging process between the check nodes and the variable nodes based on scheduling information representing an order of exchanging the messages between the check nodes and the variable nodes, wherein the scheduling information may be determined by manipulating an order of the check nodes or an order of the variable nodes in the LDPC bipartite graph.

The first memory may include a plurality of memory sectors that are partitioned, and each of the memory sectors may be assigned to one or more variable nodes.

The scheduling information prevents memory-access collisions and read-before-write violations in the first memory and the second memory during the exchange of the messages between the check nodes and the variable nodes.

At least one example embodiment discloses a method of determining scheduling information for decoding. The method includes determining an order of check nodes for processing at a first memory, determining an order of variable nodes for each check node for processing at a second memory, assigning a number of sectors in the second memory to the variable nodes, the number of sectors being based on a parallelization factor, the parallelization factor representing a first number of the variable nodes that are read in one cycle and a second number of the variable nodes that are written in the one clock cycle, determining sector assignments for the variable nodes, respectively, and generating the scheduling information based on the sector assignments.

### BRIEF DESCRIPTION OF THE DRAWINGS

Example embodiments of inventive concepts will be more clearly understood from the following detailed description taken in conjunction with the accompanying drawings in which:

FIG. 1 is a block diagram of a memory system according to an example embodiment of inventive concepts;

FIG. 2 is a block diagram of a memory system including a plurality of channels according to another example embodiment of inventive concepts;

FIG. 3 is an exemplary view showing configurations of channels and banks in the memory system of FIG. 1 and FIG. 2;

FIG. 4 is an exemplary view showing a detailed configuration of a flash memory chip included in the memory system of FIG. 1 and FIG. 2;

FIG. 5 is a conceptual view showing an internal storage structure of a flash memory chip;

FIG. 6 is a diagram showing software of the processor shown in FIG. 1;

FIG. 7 is an exemplary diagram of an LDPC decoder according to an example embodiment of inventive concepts;

FIG. 8 is an exemplary view of a configuration of a logic device module shown in FIG. 7;

FIG. 9 is an exemplary view of a first memory and a logic device module in a low density parity check (LDPC) shown in FIG. 7;

FIG. 10 is a diagram showing an example of an LDPC bipartite graph according to an example embodiment of inventive concepts;

FIG. 11 is a diagram showing serial checks equivalently representing the LDPC bipartite graph of FIG. 10 and a list of serial variables for each check node;

FIG. 12 is a diagram showing an example of an LDPC schedule table according to the serial checks and the serial variable list according to the check node shown in FIG. 10;

FIG. 13 is a diagram showing an example of allocating variable nodes to memory sectors partitioned into six;

FIG. 14 is a diagram showing a memory access schedule table corresponding the LDPC schedule table shown in FIG. 12, based on the memory sector assignment list to the variable nodes shown in FIG. 13;

FIG. 15 is a diagram showing an example of reordering the check nodes in a serial-check list and a serial-variable list for each check node shown in FIG. 11;

FIG. 16 is a diagram showing an example of reordering the variable nodes in the serial-check list and a serial-variable list for each check node shown in FIG. 15;

FIG. 17 is a diagram showing an example of changing a memory sector assignment in the memory sector assignment list to the variable nodes shown in FIG. 13;

FIG. 18 is a diagram exemplary showing LDPC schedule table according to a serial-check list in which the order of the check nodes and the order of the variable nodes shown in FIG. 16 are rearranged and a serial-variable list of each check node;

FIG. 19 is a diagram showing a memory access schedule table corresponding to the LDPC schedule table shown in FIG. 18 based on the memory sector assignment list to the variable nodes shown in FIG. 17;

FIG. 20 is a flowchart illustrating an LDPC decoding method according to an example embodiment of inventive concepts;

FIG. 21 is a flowchart illustrating a method of determining scheduling information according to an example embodiment of inventive concepts;

FIG. 22 is a flowchart illustrating a method of determining scheduling information according to the example embodiment of inventive concepts;

FIG. 23 is a block diagram of an electronic system adopting the memory system according to the example embodiment of inventive concepts;

FIG. 24 is a block diagram of a memory card system adopting the memory system according to the example embodiment of inventive concepts; and

FIG. 25 is a block diagram of an example of configuring a network of a server system including SSD according to an example embodiment of inventive concepts.

### DETAILED DESCRIPTION OF EXAMPLE EMBODIMENTS

Hereinafter, example embodiments will be described more fully with reference to the accompanying drawings. Example embodiments may, however, be embodied in many different forms and should not be construed as limited to those set forth herein. Rather, example embodiments are provided so that this disclosure will be thorough and complete, and will fully convey the scope of inventive concepts to those skilled in the art. As inventive concepts allow for various changes and numerous embodiments, example embodiments will be illustrated in the drawings and described in detail in the written description. However, this is not intended to limit example embodiments to particular modes of practice, and it is to be appreciated that all changes, equivalents, and substitutes that do not depart from the spirit and technical scope of inventive concepts are encompassed in inventive concepts. In the drawings, lengths and sizes of layers and regions may be exaggerated for clarity.

The terminology used herein is for the purpose of describing particular embodiments only and is not intended to be limiting of inventive concepts. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items. Expressions such as “at least one of,” when preceding a list of elements, modify the entire list of elements and do not modify the individual elements of the list.

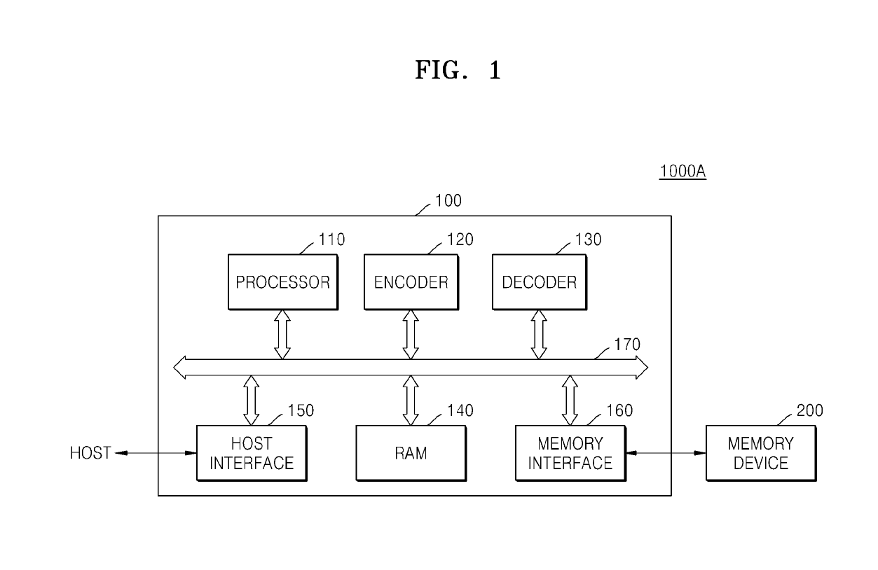

FIG. 1 is a block diagram of a memory system 1000A according to an example embodiment of inventive concepts.

As shown in FIG. 1, the memory system 1000A includes a memory controller 100 and a memory device 200.

The memory device 200 may be a non-volatile memory device. For example, the memory device 200 may be a flash memory device, a phase change random access memory (PRAM), a ferroelectric RAM (FRAM), or a magnetic RAM (MRAM) device.

The memory device 200 may be configured to include at least one non-volatile memory device and at least one volatile memory device, or at least two or more kinds of non-volatile memory devices.

In addition, the memory device 200 may be configured as a single flash memory chip, or multiple flash memory chips.

The memory controller 100 includes a processor 110, an encoder 120, a decoder 130, a RAM 140, a host interface 150, a memory interface 160, and a bus 170.

The processor 110 is electrically connected to the encoder 120, the decoder 130, the RAM 140, the host interface 150, and the memory interface 160 via the bus 170.

The bus 170 denotes a transfer path through which information is transferred between elements of the memory controller 100.

The processor 110 controls overall operations of the memory system 1000A. In particular, the processor 110 reads commands transmitted from a host and controls the memory system 1000A to perform an operation according to the read result.

The processor 110 provides the memory device 200 with a read command and an address during a reading operation, and provides the memory device 200 with a write command, an address, and an encoded codeword during a writing operation. In addition, the processor 110 converts a logical address received from the host into a physical page address by using metadata stored in the RAM 140.

The RAM 140 temporarily stores data transmitted from the host and data generated by the processor 110, or data read out from the memory device 200. Also, the RAM 140 may store metadata read out from the memory device 200. In addition, the RAM 140 may store scheduling information obtained by manipulating a low density parity check (LDPC) bipartite graph read from the memory device 200. The scheduling information may include information representing message exchange order between check nodes and variable nodes of the LDPC bipartite graph. The RAM 140 may be a DRAM or an SRAM.

Metadata is information generated by the memory system 1000A in order to manage the memory device 200. The metadata, that is, managing information, includes mapping table information that is used to convert logical addresses into physical page addresses of the memory device 200. For example, the metadata may include page mapping table information that is necessary to perform an address mapping process per page unit. Also, the metadata may include information for managing storages of the memory device 200.

The host interface 150 includes a protocol for data exchange with a host connected to the memory device 200, and connects the memory device 200 and the host to each other. The host interface 150 may be realized as an advanced technology attachment (ATA) interface, a serial advanced technology attachment (SATA) interface, a parallel ATA (PATA) interface, a universal serial bus (USB) interface or a serial attached small (SAS) computer system interface, a small computer system interface (SCSI), embedded multimedia card (eMMC) interface, or a unix file system (UFS) interface. However, inventive concepts are not limited to the above examples. In particular, the host interface 150 may exchange commands, addresses, and data with the host according to control of the processor 110.

The memory interface 160 is electrically connected to the memory device 200. The memory interface 160 may support the interface with a NAND flash memory chip or a NOR flash memory chip. The memory interface 160 may be configured so that software and hardware interleaved operations may be selectively performed via a plurality of channels.

The processor 110 controls the memory system 1000A to read the metadata stored in the memory device 200 and store the metadata in the RAM 140, when an electric power is supplied to the memory system 1000A. The processor 110 controls the memory system 1000A to update the metadata stored in the RAM 140 according to an operation of generating metadata change in the memory device 200. In addition, the processor 110 controls the memory system 1000A to write the metadata stored in the RAM 140 in the memory device 200 before the memory system 1000A is turned off (POWER OFF).

The processor 110 controls the memory controller 100 to perform an LDPC encoding process of information words transmitted from the host in the encoder 120 during the writing operation, and to perform an LDPC decoding process of the data read from the memory device 200 in the decoder 130 during the reading operation.

The encoder 120 generates codeword by adding a plurality of parity bits represented by an LDPC code to the information word transmitted from the host. If the bit number of the codeword is N and the bit number of the information word is K, the parity bit number is N-K. Each of the parity bits of the LDPC codeword is set to satisfy the LDPC code.

The decoder 130 performs the LDPC decoding process of the data read from the memory device 200 by a codeword unit to recover the information word.

The LDPC codes may be represented by a bipartite graph that is referred to as a Tanner graph. That is, an edge may connect a variable node only to a check node, and may not connect the variable node to another variable node or the check node to another check node. In such a graph, a set of nodes, that is, variable nodes, correspond to bits of the codeword and another set of nodes, and constraint nodes that are referred to as check nodes correspond to a set of parity check constraints defining a code.

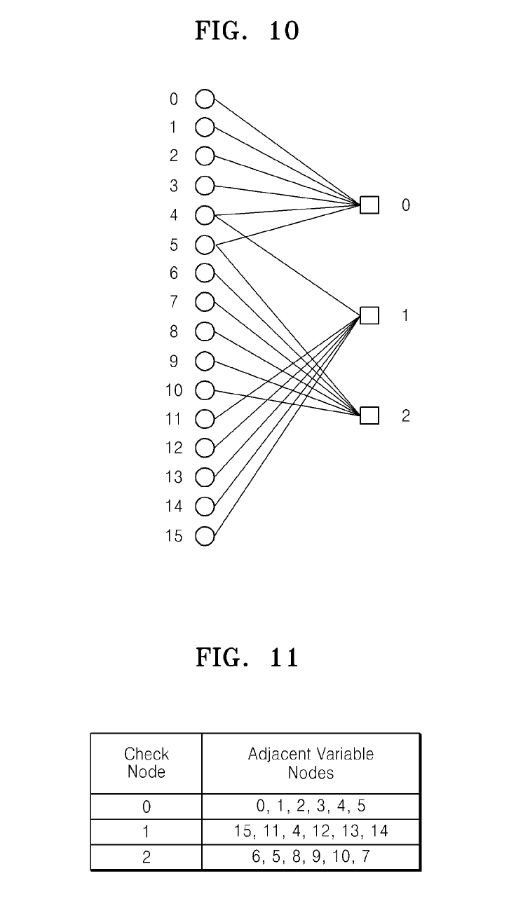

The decoder 130 repeatedly performs check node update and variable node update while exchanging messages between the variable nodes and the check nodes based on an LDPC bipartite graph, for example, as shown in FIG. 10, until an error determination does not occur.

The decoder 130 performs the LDPC decoding process based on scheduling information obtained by manipulating the LDPC bipartite graph. Here, the scheduling information may include information representing a message exchange order between the check nodes and the variable nodes for LDPC decoding. The scheduling information is determined so as to satisfy conditions where memory access collisions and read-before-write violations do not occur, by manipulating an order of the check nodes or an order of the variable nodes from the LDPC bipartite graph. The configurations and operations of the decoder 130 will be described in detail below.

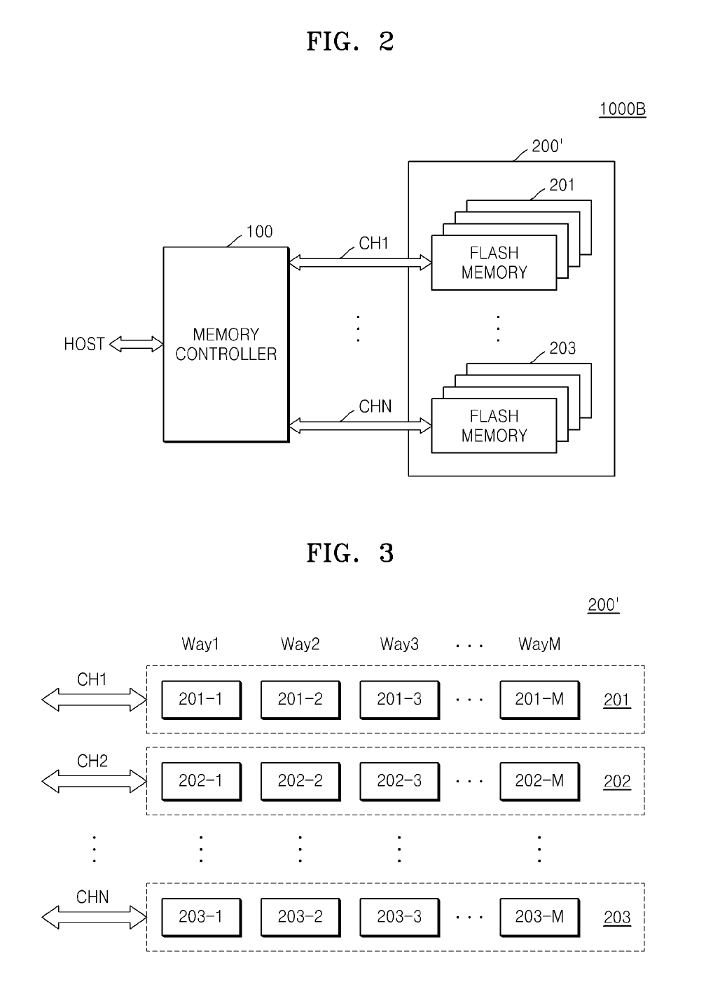

FIG. 2 is a block diagram of a memory system 1000B forming a plurality of channels and a plurality of ways by configuring the memory device 200 shown in FIG. 1 with a plurality of memory chips.

The memory system 1000B having the structure of FIG. 2 may configure a solid state drive (SSD). The SSD may be referred to as a solid state disc.

Referring to FIG. 2, a memory device 200′ of the memory system 1000B includes a plurality of flash memory chips 201 and 203.

The memory system 1000B includes first through N-th channels CH1-CHN (N is a natural number) and each of the channels may include flash memory chips. The number of flash memory chips included in each of the channels may vary.

The memory controller 100 of FIG. 2 is substantially the same as the memory controller 100 of FIG. 1, and detailed descriptions thereof are not provided here.

FIG. 3 is a diagram exemplary showing structures of the channels and ways in the memory system 1000B of FIG. 2.

A plurality of flash memory chips 201, 202, and 203 may be electrically connected to each of the channels CH1 through CHN. Each of the channels CH1 through CHN may denote an independent bus that may transmit/receive commands, addresses, and data to/from the corresponding flash chips 201, 202, and 203. The flash memory chips connected to different channels may operate independently from each other. The plurality of flash memory chips 201, 202, and 203 connected to the channels CH1 through CHN may form a plurality of ways way1 through wayM. M number of flash memory chips may be connected to the M ways formed with respect to each of the channels CH1 through CHN.

For example, flash memory chips 201 may configure M ways way1 through wayM in the first channel CH1. Flash memory chips 201-1 through 201-M may be connected respectively to the M ways way 1 through wayM in the first channel CH1. Such relationships between the flash memory chips and the ways may be applied to the flash memory chips 202 and the flash memory chips 203.

The way is a unit for distinguishing the flash memory chips sharing the same channel. Each of the flash memory chips may be identified according to the channel number and the way number. It may be determined which flash memory chip performs the request provided from the host according to the logical address transmitted from the host.

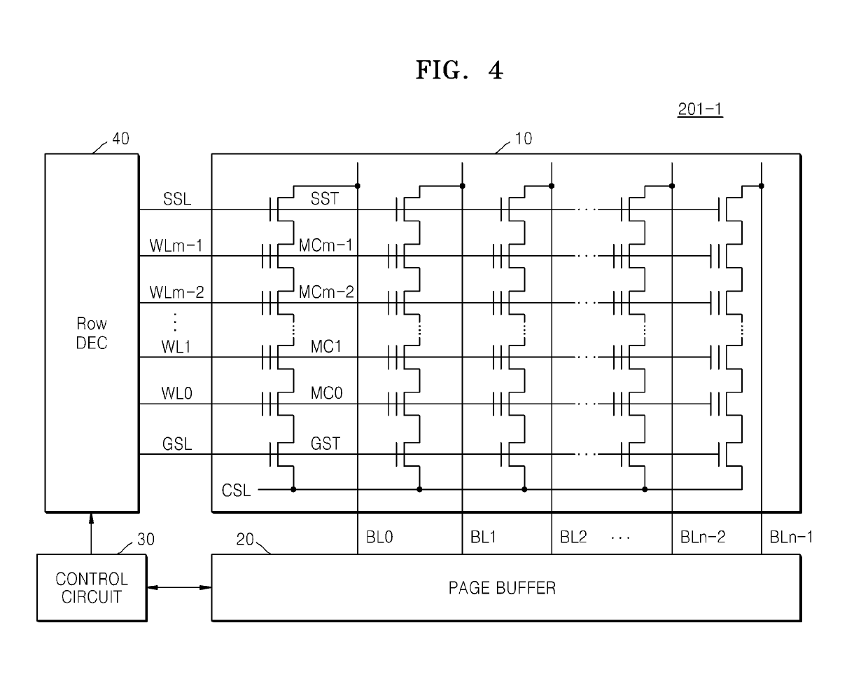

FIG. 4 is a diagram exemplary showing a circuit configuration of one flash memory chip 201-1 forming the memory device 200′ of FIG. 3.

As shown in FIG. 4, the flash memory chip 201-1 may include a cell array 10, a page buffer 20, a control circuit 30, and a row decoder 40.

The cell array 10 is an area in which data is written by applying a voltage to a transistor. The cell array 10 includes memory cells formed on points where word lines WL0 through WLm-1 and bit lines BL0 through BLn-1 cross each other. Here, m and n are natural numbers. In FIG. 4, only one memory block is shown; however, the cell array 10 may include a plurality of memory blocks. Each of the memory blocks includes a page corresponding to each of the word lines WL0 through WLm-1. In addition, each page may include a plurality of memory cells connected to the corresponding word line. The flash memory chip 201-1 performs an erasing operation with respect to each memory block, and performs a programming operation or a reading operation with respect to each page.

The memory cell array 10 has a cell string structure. Each of cell strings includes a string selection transistor (SST) connected to a string selection line (SSL), a plurality of memory cells MCO through MCm-1 respectively connected to the plurality of word lines WL0 through WLm-1, and a ground selection transistor (GST) connected to a ground selection line (GSL). Here, the SST is connected between the bit line and a string channel, and the GST is connected between the string channel and a common source line (CSL).

The page buffer 20 is connected to the cell array 10 via the plurality of bit lines BL0 through BLn-1. The page buffer 20 temporarily stores data that will be written in the memory cells connected to the selected word line, or the data read from the memory cells connected to the selected word line.

The control circuit 30 generates various voltages necessary to perform the programming operation or the reading operation, and the erasing operation, and controls overall operations of the flash memory chip 201-1.

The row decoder 40 is connected to the cell array 10 via the SSL, the GSL, and the plurality of word lines WL0 through WLm-1. The row decoder 40 receives an address during the programming operation or the reading operation, and selects one of the word lines according to the input address. Here, the memory cells for performing the programming operation or the reading operation are connected to the selected word line.

Also, the row decoder 40 applies voltages that are necessary for the programming operation or the reading operation (for example, a programming voltage, a pass voltage, a reading voltage, a string selection voltage, and a ground selection voltage) to the selected word line, non-selected word lines, and the selection lines (SSL and GSL).

Each of the memory cells may store data of one bit or two or more bits. The memory cell storing the data of one bit may be referred to as a single level cell (SLC). In addition, the memory cell storing the data of two or more bits may be referred to as a multi-level cell (MLC). The SLC is in an erase state or a program state according to a threshold voltage thereof.

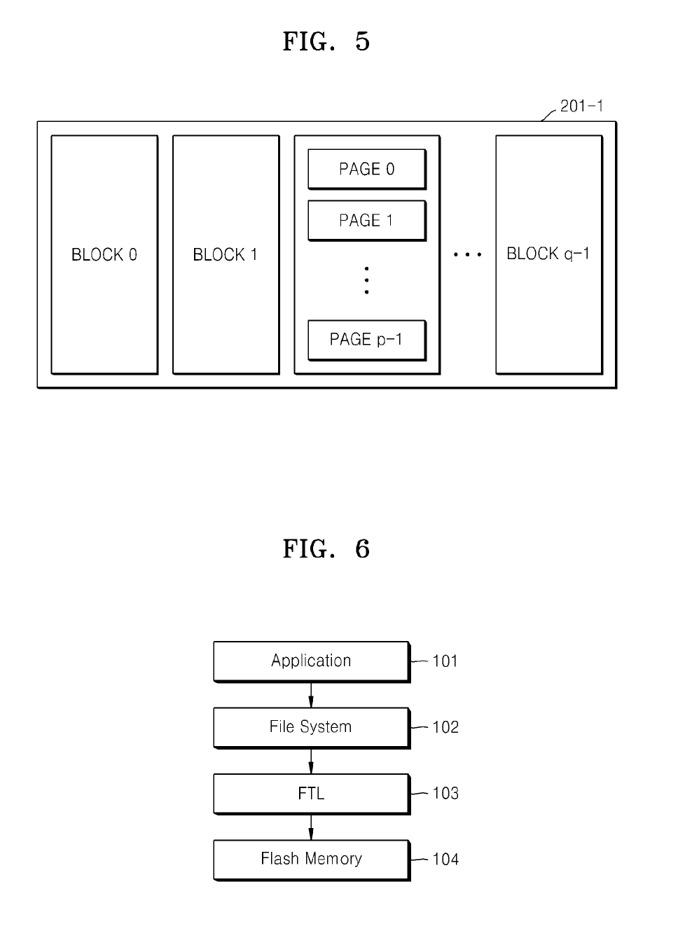

As shown in FIG. 5, the flash memory chip 201-1 includes a plurality of blocks therein, and each of the blocks includes a plurality of pages.

In the flash memory chip 201-1, the writing and reading of the data is performed per page unit, and an electric erasing is performed per block unit. In addition, the electric erasing operation of the block has to be performed before performing the writing operation. Accordingly, overwriting may not be possible.

In the memory device that is not capable of performing the overwriting, the user data may not be written in a physical area desired by the user. Therefore, when the host request to access in order to write or read data, an address conversion operation for converting the logical address representing an area that is requested to write or read data into a physical page address representing a physical area actually storing the data or will store the data is necessary.

Processes of converting the logical address into the physical page address in the memory system 1000A or 1000B will be described with reference to FIG. 6.

FIG. 6 is a block diagram showing software configuration of the memory system 1000A or 1000B. As an example, FIG. 6 shows software configuration in a case where the memory device 200 is formed as a flash memory.

Referring to FIG. 6, the memory system 1000A or 1000B has a software hierarchical structure including an application layer 101, a file system layer 102, a flash translation layer (FTL) 103, and a flash memory layer 104.

The application layer 101 denotes firmware processing data in response to the user input from the host. In the application layer 101, the user data is processed in response to the user input, and a command for storing the processed user data in a flash memory chip is transmitted to the file system layer 102.

In the file system layer 102, a logical address in which the user data will be stored is allocated in response to the command transmitted from the application layer 101. A file allocation table system or NTFS may be used as the file system in the file system layer 102.

In the FTL 103, the logical address transmitted from the file system layer 102 is converted to the physical page address for performing the writing/reading operations in the flash memory chip. In the FTL 103, the logical address may be converted into the physical page address by using mapping information included in the metadata. The address conversion operation in the FTL 103 may be performed by the processor 110 of the memory controller 100.

In the flash memory layer 104, control signals for storing or reading data by accessing the physical page address converted from the logical address are generated.

FIG. 7 is a diagram exemplary showing an LDPC decoder 130A that is a modified example of the decoder 130 of FIG. 1.

As shown in FIG. 7, the LDPC decoder 130A includes a first memory (VND) 131, a logic device module 132, a second memory (CND) 133, and a control device 134.

The first memory 131 stores states of variable nodes in the LDPC bipartite graph. As an example, the first memory 131 includes a plurality of memory sectors that are partitioned, and each of the memory sectors may be allocated to one or more variable nodes.

The second memory 133 stores states of the check nodes in the LDPC bipartite graph.

For example, the first and second memories 131 and 133 may be configured so that the states of the nodes included in the same block may be stored in the same memory row. Here, the block is a collection of the nodes obtained from the expansion of a specific protograph node. When the first and second memories 131 and 133 are designed as described above, the states of the nodes stored in the same memory row may be accessed in parallel in one clock cycle.

The logic device module 132 includes logic circuits that are respectively connected to the first memory 131 and the second memory 133 for performing calculations for exchanging messages between the check nodes and the variable nodes. The logic device module 132 may be designed so that P number of variable nodes may be processed in parallel, and for example, if P is 4, in pass 1 in which the messages are sent from the variable nodes to the check nodes, four variable nodes send messages to the check node, and in pass 2 in which messages are sent from the check nodes to the variable nodes, the check node sends messages to four variable nodes. Here, P is referred to as a parallelization factor.

The control device 134 controls the logic device module 132 to perform the message exchange between the check nodes and the variable nodes based on scheduling information obtained by manipulating the LDPC bipartite graph. The scheduling information is determined so as to satisfy conditions under which the memory access collisions and read-before-write violations do not occur in the first and second memories 131 and 133 during the message exchange between the check nodes and the variable nodes.

According to the message exchange process, the variable nodes are updated in the first memory 131, and the check nodes are updated in the second memory 133.

The control device 134 performs the LDPC decoding process based on results of the variable node update according to the message exchange. For example, the control device 134 reads the states of the updated variable nodes from the first memory 131 to perform a tentative decoding process, and after that, determines whether there is an error in the tentative decoding processing result. As an example, the control device 134 may determine whether there is an error based on hard decision of the states of the variable nodes.

If it is determined there is an error as a result of the tentative decoding process, the control device 134 controls the logic device module 132 to perform the check node update and the variable node update according to the message exchange. If it is determined that there is no error as a result of the tentative decoding process, the hard decision result of the state of the updated variable node is output as decoded data.

The control device 134 may control the logic device module 132 to perform the message exchange process between the check nodes and the variable nodes based on the scheduling information according to, for example, a row-by-row scheduling process, a serial check X (SCX) scheduling process, or a block-serial-check X (BSCX) scheduling process.

In the row-by-row scheduling process, the check nodes are processed in series according to a few orders defined in advance. The processes of the check nodes consist of two passes. In each of the passes, neighboring variable nodes are processed in series according to an order.

Pass 1: Variable Node→Check Node

Each adjacent variable node sends a message to the check node. The check node computes a new state, based on the messages.

Pass 2: Check Node→Variable Node

The check node sends a message to each adjacent variable node. The variable nodes update states thereof based on the received messages.

The SCX scheduling process is similar to the serial-check scheduling process, except that a fixed number P variable nodes are processed in parallel rather than processing the variable nodes serially.

The BSCX scheduling process is similar to the SCX scheduling process; however, multiple messages are exchanged in parallel in order to speed-up the performance. In particular, in each clock cycle, messages are transmitted across the parallel edges that were expanded from the same edge in the protograph.

The BSCX scheduling process with parallel passes (BSCXP) may perform the process of pass 2 in parallel with the processing of pass 1 of the next protograph check node in order to speed up performance.

Hereinafter, the BSCXP scheduling process will be described. However, inventive concepts are not limited thereto, that is, may be applied to various types of scheduling processes.

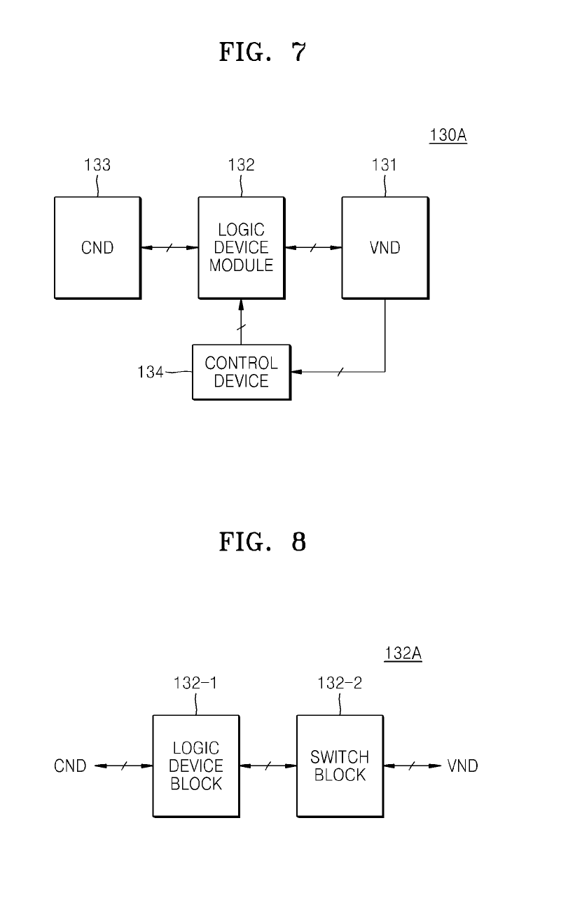

FIG. 8 is a diagram exemplary showing a configuration of the logic device module 132 shown in FIG. 7.

As shown in FIG. 8, the logic device module 132A includes a logic device block 132-1 and a switch block 132-2.

The switch block 132-2 is respectively connected to the first memory 131 and the logic device block 132-1. The switch block 132-2 switches signal passages between the first memory 131 and the logic device block 132-1 so that the message is exchanged between the check node and the variable node according to the control signal generated by the control device 134 based on the scheduling information that is obtained by manipulating the LDPC bipartite graph.

The logic device block 132-1 performs calculations of the messages that will be exchanged between the check nodes and the variable nodes, and the calculated messages are exchanged via the signal passages that are switched by the switch block 132-2.

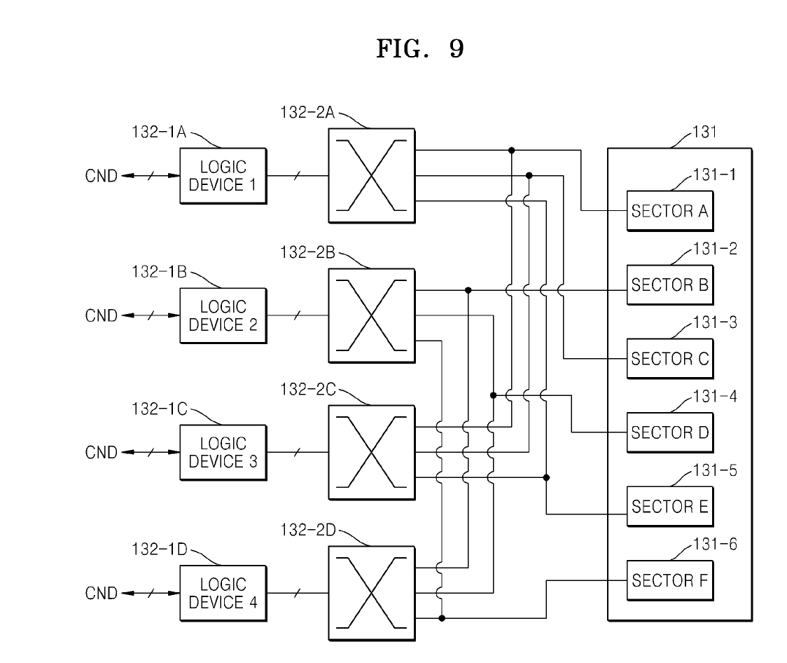

FIG. 9 is a diagram exemplary showing a configuration of the first memory and the logic device module 132 of the LDPC decoder shown in FIG. 7.

As shown in FIG. 9, the first memory 131 is partitioned into six memory sectors A through F 131-1 through 131-6. This denotes that the variable nodes are separately allocated to the six memory sectors A through F 131-1 through 131-6.

In addition, the logic device module 132 consists of four logic devices 1 through 4 131-1A through 131-1D and four switches 1 through 4 132-2A through 132-2D. In the above example, two variable nodes of pass 1 are processed in parallel, and at the same time, two variable nodes of pass 2 are processed in parallel.

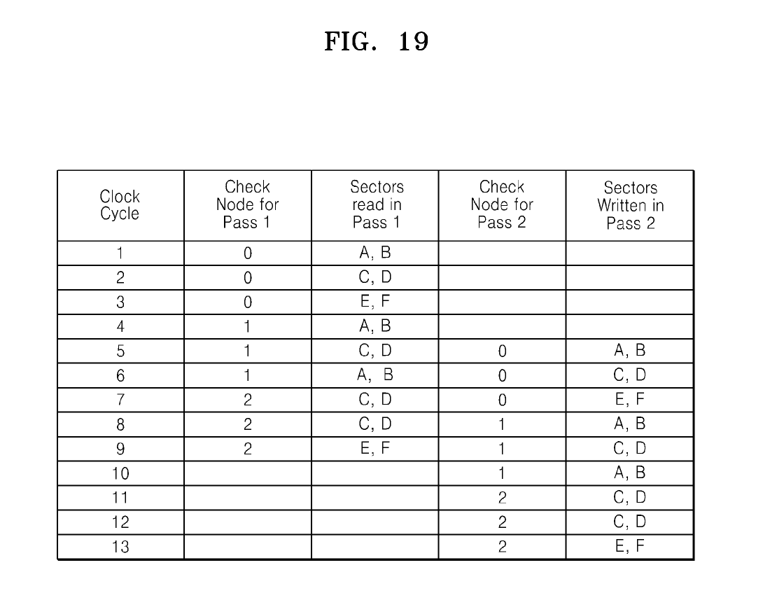

FIG. 9 shows an example of designing wires of the LDPC decoder for performing the message exchange according to a memory access schedule table shown in FIG. 19.

Referring to FIGS. 9 and 19, the logic devices 1 and 3 132-1A and 132-1C are limited to the memory sectors A, C, and E 131-1, 131-3, and 131-5, and the logic devices 2 and 4 are limited to the memory sectors B, D, and F 131-2, 131-4, and 131-6. Accordingly, complexity of the wires of the LDPC decoder may be reduced.

Next, a method of determining the scheduling information by manipulating the LDPC bipartite graph according to inventive concepts will be described below.

First, following memory access collisions, read-before-write violations, and routing congestion may be accompanied when the message exchanges between the check nodes and the variable nodes are performed in parallel.

<Memory Access Collision>

Referring to FIG. 7, transmission of a message from/to the variable node involves reading/writing operation of the states of the variable nodes from/to the first memory 131. As an example, in the BSCXP scheduling process, multiple memory accesses are required in each clock cycle. However, single port memories allow only one memory access per one clock cycle. Accordingly, if more than one access is necessary, a collision occurs.

One solution to this problem is to partition the first memory 131 into sub-memories called sectors. Each of the sub-memories stores a part of the states of the variable node blocks. Even with this partition, in an arbitrary LDPC graph, multiple accesses may frequently occur to the same sectors.

<Read-Before-Write Violation>

The parallel execution of pass 1 and pass 2 in the BSCXP scheduling process implies the potential of data-integrity problems. In particular, in pass 1, it is assumed that the states of all variable nodes in the first memory 131 are correct and up-to-date. If pass 2 of the previous check node has not yet concluded, some of the states of the variable nodes are out-dated. Accordingly, parallel execution of pass 1 and pass 2 may generate the read-before-write violation.

<Routing Congestion>

Computations of messages from/to variable nodes are performed by the logic device module 132. For example, when it is assumed that P is 4 in the BSCXP scheduling process, eight logic devices are necessary. Four logic devices are necessary for messages from the variable nodes, and four logic devices are necessary for messages to the variable nodes. If the multiple memory sectors (for example, eight) are used, each of the eight logic devices needs to be wired to each of the eight memory sectors, and thereby increasing complexity of routing.

To address the above problems, following solutions may be considered.

<Dual-Port Memories>

With such memories, two accesses per memory are allowed in each clock cycle.

However, such memories have increased die-sizes.

<Restricting LDPC Graph>

An LDPC graph having a desired expansion ratio (block length) z may be obtained by transforming a graph with expansion ratio 8z. As a result, a graph may be shown to exhibit no memory-access collisions (assuming that a partition of a memory is 8 sections). However, for a given codeword length, codes with expansion ratio 8z are further restricted, and poor performances are shown in view of error resilience and throughput.

<Dedicated Hardware>

The memory access collisions and the read-before-write violations may be addressed by pausing in dedicated hardware. However, such hardware increases complexity and verification time, and pauses reduce throughput.

Inventive concepts provide a solution to the memory-access collisions and the read-before-write violations in order to address the above problems. Also, a method for reducing routing problems is disclosed.

The solution is to manipulate the orders by which nodes are accessed in the BSCXP schedule, for example. In particular, the order by which check nodes are processed and the order by which the neighboring variable nodes of the check nodes are processed in passes 1 and 2 are manipulated. Such manipulations do not affect the encoder, that is, do not affect performances of the codes (error correcting and decoding times). Thus, the solution is not applied to the fixed codes and the encoder, but applied to the decoder.

As an example, a method of determining scheduling information by manipulating the LDPC bipartite graph will be described below.

Nodes and edges shown in the graph of FIG. 10 may be represented equivalently as a list shown in FIG. 11.

Referring to FIG. 11, the list shows an arbitrary order by which check nodes are processed when applying, for example, a BSCXP schedule, and the order denotes an order of the variable nodes adjacent to the check nodes processed in pass 1 and pass 2.

For example, if a parallelization factor P is 2, an LDPC schedule table shown in FIG. 12 may be obtained.

Referring to FIG. 12, a decoding begins by processing check node 0. Since the parallelization factor P is 2, two variable nodes may be read and two variable nodes may be written in each clock cycle. Here, “reading” or “writing” a variable node denotes reading or writing the states of variable nodes corresponding to the blocks from/to the first memory 131.

In clock cycle 1, variable nodes 0 and 1 are processed. In FIG. 12, the variable nodes 0 and 1 are first two variable nodes in the list of adjacent variable nodes to check node 0. In clock cycle 3, pass 1 for check node 0 is finished, and pass 1 process for check node 1 begins in clock cycle 4.

In addition, in clock cycle 5, pass 2 process for check node 0 begins. In this clock cycle, variable nodes 0 and 1 are processed. The order by which the variable nodes are accessed in pass 2 is the same as that used in pass 1.

For convenience of description, only one LDPC decoding repetition is assumed in FIG. 12; however, the LDPC decoding is repeatedly used. That is, when pass 1 of the check node 2 is finished, a second pass 1 of the check node 0 starts. This makes removal of memory-access collision and read-before-write violations complicated.

Pass 2 of the check node 0 may begin in clock cycle 4, not clock cycle 5. This is because read operations of pass 1 of check node 0 have finished in clock cycle 3. However, a hardware pipeline needs a few more clock cycles to finish processing of data of pass 1.

This kind of delay may be referred to as a delay factor d. For example, if d=1, pass 2 begins in clock cycle 5. The delay factor d may be set differently in consideration of system characteristics.

Referring to FIG. 12, a state of a variable node 4 is read in clock cycles 3 and 5. In clock cycles 7 and 9, the variable node 4 is updated (written). This denotes that the state that is read in clock cycle 5 is out-dated. Accordingly, a read-before-write violation occurs.

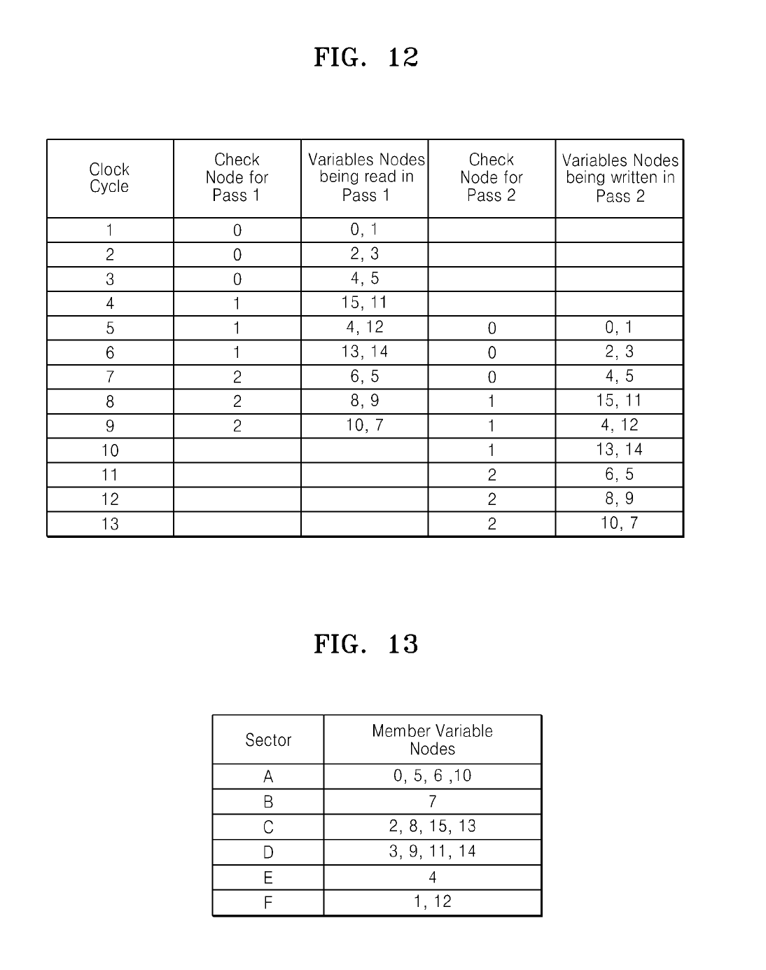

FIG. 13 shows an example in which the variable nodes are partitioned into six sectors.

Referring to the table shown in FIG. 13, the first memory 131 is partitioned into six memory sectors, which are referred to as sectors A. B, C, D, E, and F. For example, the memory sector A stores states of the block corresponding to variable nodes 0, 5, 6, and 10.

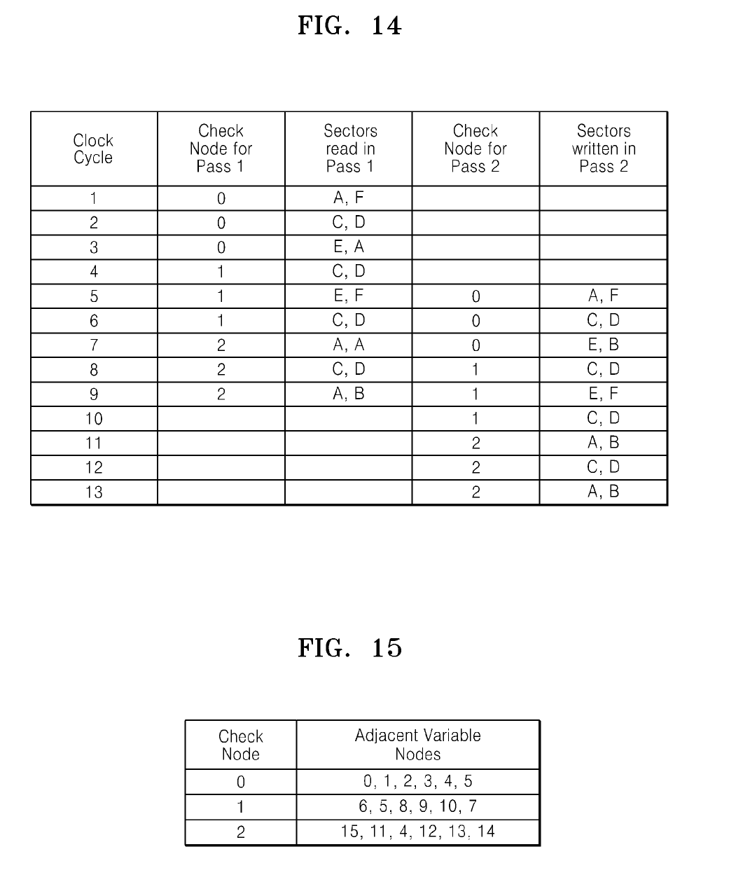

FIG. 14 shows a memory access schedule table corresponding to the LDPC schedule table of FIG. 12, based on the memory sector allocation list to the variable nodes shown in FIG. 13.

Referring to FIG. 12, the variable nodes 0 and 1 are read in clock cycle 1, and according to the table of FIG. 13, the variable node 1 belongs to the memory sector A and the variable node 1 belongs to the memory sector F. Accordingly, the memory sectors A and F are read in clock cycle 1, as shown in FIG. 14.

Referring to FIG. 14, a lot of memory-access collisions are shown. For example, in clock cycle 5, the memory sector F needs to be both read and written. In clock cycle 7, the memory sector A has to be read twice.

In order to address the memory-access collisions and the read-before-write violations generated in the memory access schedule shown in FIG. 14, the serial check and the serial variable nodes list according to the check nodes shown in FIG. 11 and the memory sector allocation table shown in FIG. 13 may be manipulated as follows.

Step 1: Reordering Check Nodes

In this step, left columns of rows 1 and 2 are simply exchanged as shown in FIG. 15. This is like renaming of the check nodes 1 and 2.

Step 2: Reordering Adjacent Variable Nodes

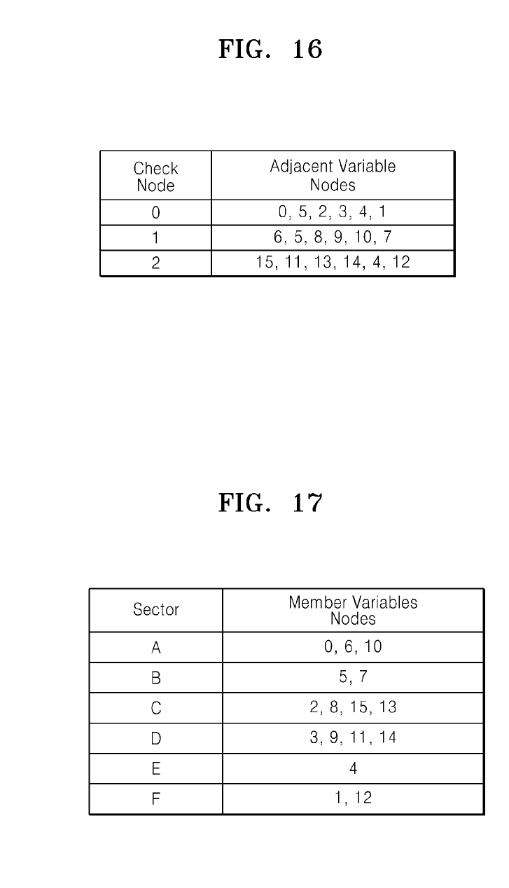

For example, order of variable nodes 1 and 5 in the list of adjacent variable nodes of the check node 0 is changed. In addition, variable nodes 5 and 7 that are adjacent to the check node 1 are changed, and pairs of adjacent variable nodes (4, 12) and (13, 14) of the check node 2 are exchanged. When exchanging the order of the variable nodes, changed serial check and serial variable nodes list according to the check nodes as shown in FIG. 16 may be obtained.

Step 3: Changing Sector Assignments to Variable Nodes

Assignment of the variable node 5 is changed from the memory sector A to the memory sector B as shown in FIG. 17.

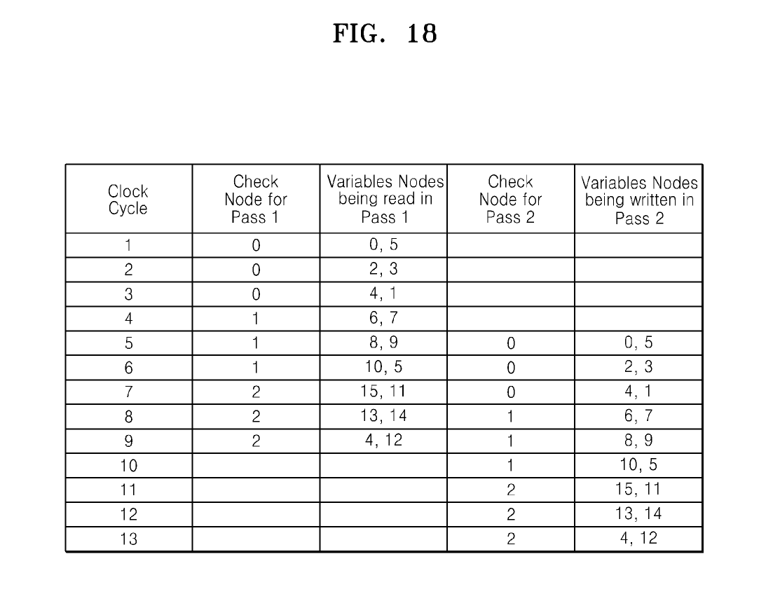

When applying the changes according to the steps 1 through 3, a new LDPC schedule table shown in FIG. 18 and a new memory access schedule table shown in FIG. 19 may be obtained.

Referring to FIG. 18, there is no read-before-write violation. In addition, referring to FIG. 19, there is no memory-access collision.

As described above, the routing congestion problem results from wiring between memory sectors and logic devices. In the above embodiments, six memory sectors are used. Also, four logic devices are necessary for processing two variable nodes of pass 1 and two variable nodes of pass 2.

It is assumed that logic devices 1 and 2 support calculations of pass 1. In clock cycle 1, the logic device 1 needs to obtain data read from sector A, and the logic device 2 needs to obtain data from sector B. Similarly, logic devices 3 and 4 support the calculations of pass 2. In clock cycle 5, the output of the logic device 3 needs to be written to sector A, and the output of the logic device 4 needs to be written the sector B.

A naive implementation would wire each of the logic devices to each of the 6 memories. However, referring to table shown in FIG. 19, the logic devices 1 and 3 may be confined to memory sectors A, C and E, while the other two to memory sectors B, D and F. An example of wiring design of the six memory sectors and the logic devices is shown in FIG. 9. Accordingly, complexity of the wiring may be reduced.

The above described reordering of the graph and the rearrangement of the memory sectors may be designed to reduce the routing congestion.

To summarize, a generalized method is as follows.

Graph representation is manipulated by reordering (renumbering) check nodes and reordering variable nodes adjacent to the check nodes. Also, the variable nodes are assigned to the memory sectors. The resulting configuration has to satisfy following conditions:

1. There is no read-before-write violations;

2. There is no memory-access collision; and

3. To reduce routing congestion, each of 2P logic devices needs to be configured as small a number of sectors as possible.

Following additional requirements may be applied as options.

<Minimization of the Number of Sectors>

When the first memory 131 is partitioned into more sectors, assignment of the variable nodes to the first memory 131 may be simplified in a way of eliminating the memory-access collisions. However, if the first memory 131 is partitioned into more sectors, memory efficiency (logic gates per memory bit) is lowered. The minimum number of sectors is 2P, that is the maximum number of memory accesses per clock cycle.

<Balance of Sizes of Sectors>

To achieve memory efficiency (logic gates per memory bit), the memories are balanced, in terms of the number of variable nodes contained therein.

Although the BSCXP schedule is described above in inventive concepts, inventive concepts may be applied to other scheduling processes. For example, in a block serial-variable schedule, multiple check node memory access is necessary in order to read or write states of the check nodes. A method provided by inventive concepts may be applied to reschedule the memory accesses, and may be applied to adaptively partition the second memory 133 in which states of the check nodes are stored in order to reduce the memory-access collisions. Even when inventive concepts are applied to other schedules, the read-before-write violations and the routing congestions may be reduced similarly.

An actual graph includes hundreds of nodes, each connected to different nodes. As another example, the following algorithm may be used to achieve this.

For convenience of description, in algorithms, a parallelization factor P is set as 4. An arbitrary P may be modified.

Algorithm 1: eliminate memory-access collisions and read-before-write violations

The following algorithm applies an algorithm 2 to eliminate memory-access collisions, and an algorithm 3 to eliminate read-before-write violations. The output also satisfies the additional requirements as described above.

Algorithm includes following steps:

Step 1A: Applying Algorithm 2

Check nodes and adjacent variable nodes are reordered, and the variable nodes are assigned to memory sectors (“colors”).

Step 2A: Result Evaluation

It is verified whether the sector assignments meet sector size requirements. If not, restart at step 1A.

Step 3A: Applying Algorithm 3

The check nodes and adjacent variable nodes are reordered to eliminate read-before-write violations.

Step 4A: Result Evaluation

If any read-before-write violations remain at the output of algorithm 3, restart at step 1A.

Simple techniques used to identify graphs do not exist as a solution. Specifically, check nodes that are adjacent to the same variable nodes are separated. If CND degree is 40, then it can be shown that the read-before-write constraint cannot be satisfied if we have three consecutive check nodes adjacent to the same variable node. If a check node degree is 40 and if three consecutive check nodes adjacent to the same variable node exist, it is not easy to find a solution for eliminating the read-before-write violations.

In algorithm 2 that will be described below, variable nodes are partitioned into eight sectors. A first partition is into two sectors, each partitioned into two sub-sectors, and then, four sectors are obtained. Finally, the above operation is repeated to obtain eight sectors.

The algorithm 2 will be described in detail below.

Algorithm 2: removal of memory-access collisions

In the description below, the variable nodes may be assigned to the memory sectors by using a “coloring” algorithm. The color of the sector is assigned within a range {0, . . . 7}. Formal notation and algorithm will be described below.

Notation

1. Variable Nodes

N denotes the number of variable nodes, and [N]={1, . . . , N} is the set of variable nodes.

2. Check Nodes

K denotes the number of check nodes, and [K]={1, . . . , K} is the set of check nodes.

3. Check Node Degree

L denotes the number of variable nodes per one check node, for example, 4|L.

4. Edges

For each check node k=1, . . . , K, a corresponding set of variables nodes Sₖ⊂[N], is given, such that |Sₖ|=L, and the union of all Sₖ kε[K] is [N]. It is written as a sequence by Sₖ={x(k,1), . . . , x(k,L)}, kε[K].

5. Graph Length (the Number of Edges)

M=K·L, and a target sequence length m is M/4.

6. Offset

An offset integer d satisfies inequality L/4≦d≦M/4.

Typical example: N=300, K=30, L=40.

A solution to the problem: triplet (π, σ, f)

Check node permutation π: [K]→[K]

Vector of mappings σ=(σ₁, . . . , σ_{K}), σᵢ: [L]→Sᵢ (i=1, . . . , K)

Here, σ denotes an edge permutation.

Sector (color) assignment f

Mapping f:[N]→Z₈ representing the color assignment to each of variable nodes

The offset d may be replaced with d′ε{d−1,d,d+1}.

Constraints on a valid solution will be described below.

Problem Formulation

Definition: CV and CV-4 sequences

Every choice of the mappings π and σ=(σ₁, . . . , σ_{K}) corresponds to a sequence of length M of the variable nodes numbers (i.e. 1, . . . , N). The check nodes are set in the order π and within each kε[K] check node its variable nodes are ordered by σₖ. Accordingly, the CV (check node-variable node) sequence that corresponds to π, σ: aₙ=aₙ(π,σ), 0≦n≦M−1 where aₙε[N](i.e. aₙ is check node) and for each 0≦n≦M−1, that is, K≧k≧1, 0≦j≦L−1 that satisfy n=L·(k−1)+j is defined as equation 1:

a(n)=aₙ=aₙ(π,σ)=x(π(k),σ_{π(K)}(j)) (1)

Next, CV-4 sequence (Aᵢ), which is sequence of sequences of 4 elements of {aₙ}, may be defined as equation 2:

Aᵢ=Aᵢ(π,σ)={a₄₋ᵢ,a₄₋ᵢ₊₁,a₄₋ᵢ₊₂,a₄₋ᵢ₊₃},0≦i≦m−1 (2)

For U⊂[8], equation 3 may be obtained:

−U≡(−1)·U≡U^{c}=[8]\U (3)

For given (π, σ, f), i-collision Colⱼ (0≦i≦m−1) may be defined as equation 4:

Colᵢ=Colᵢ(π,σ,f)=|Aⱼ∩A_{i⊕d}| (4)

Here, it is defined that i⊕d=mod(i+d,m). In addition, a modulo ring Zm={0, 1, . . . , m1}.

In addition, a total amount of cyclic collisions may be defined as equation 5.

Col=Col(π,σ,f)=Σ_{-0≦i≦m-1}|Aᵢ∩A_{i⊕d}| (5)

Then, (π, σ, f) satisfying following conditions are found:

(i) Col(π,σ,f) is null or at least minimized (that is, (π, σ, f) satisfying Col(π, σ, f)=0 becomes the solution to the problem);

(ii) Keep the colors as balanced as possible (that is, |f⁻¹(j)|jεZ₈ is close as possible to constant); and

(iii) the order by which each CV-4 sequence is colored with colors from the set {0, 1, 2, 3} or the set {4,5,6,7}, but not a hybrid between the two.

[Theoretical Background]

Definition of Variable Node Degree

Regarding iε[N], it is assumed that deg(i)=|kε[K]: iεSₖ)|.

An abelian group is partitioned into disjoint cosets not having common elements and relevant properties. Regarding an inequality 0≦i≦m−1, a condition Colᵢ=0 [symbol] A_{i⊕d}=Aᵢ^{c} is satisfied.

An additive abelian group Zₘ may be partitioned into mutual disjoint cosets given by (iεZₘ) Cᵢ={i⊕j·d: jεZₘ}. This may be represented as equation 6.

Cᵢ=Cₖ if mod(i−k+j·d,m)=0,jεZₘ (6)

That is, Cᵢ=Cₖ [symbol] i−kεC₀ (zero cosets is a sub-group of Zₘ).

In addition, Cᵢ∩Cₖ=Ø [symbol] i−kεC₀ is satisfied.

Additionally, |Cᵢ|=m/gcd(m, d) is satisfied.

Also, in the abelian group Zₘ, C₀+i=Cᵢ. For every Zᵢ, R(Zᵢ) may be defined to be the smallest element of Zᵢ. For example, it is set as r=gcd(m,d) and G_{m,d}=Zₘ/C₀={Cᵢ:iεZₘ} and H_{m,d}={R(Cᵢ):iεZₘ}={iᵢ, . . . iᵣ} may be defined.

Necessary condition for the existence of the solution is as follows.

[Lemma]

The existence (π,σ,f) satisfying Col(π,σ,f)=0 implies that m/gcd(m,d) is even (or equivalently M/gcd(M,d)=8).

[Proof]

For 0≦i≦m, given (π,σ,f) satisfies Colᵢ=0 [symbol] A_{i⊕d}=Aᵢ^{c}=−Aᵢ. When Col(π,σ,f)=0, a relation of A_{i⊕j·d}=(−1)^{j·}Aᵢ is satisfied for all jεZ. This implies that for all iεZₘ, i=mod(i+j·d,m), and j is even. That is, since Col(π,σ,f)=0 implies that mod(j·d·m)=0, j becomes even.

It is assumed that there is (π,σ,f) where Col(π,σ,f) is 0, and m′ is m/gcd(m,d) and d′ is m/gcd(m,d). Then, when mod(j·d′,m′) is 0, j is an even number. The equation mod(j·d′, m′)=0 denotes that there is kεZ satisfying the equation j·d′+k·m′=0.

When the above condition occurs, it may be supposed without loss of generality that gdc(k,j)=1, now if m′ is not even, an immediate contradiction may be obtained.

Following conditions are satisfied:

(1) this condition is always satisfied when 8|M and d is odd; and

(2) If it is assumed that 8|M and d is odd and additionally that |Cᵢ|≦m/3, degree of freedom increases.

[Coloring Algorithm]

The coloring algorithm works sequentially as follows.

From the first coset: {Aₛ}_{sεZm,s=mod(j·d,m)}, the second coset is calculated.

The first four A₀ are formed by going through all the check nodes, and when 4 non-colored variable nodes are found in one check-node, the sum of their degrees is maximal.

At each intermediate step, the process is performed at the beginning or the middle of some coset. A_{mod(i+j·d,m)} for some j is defined. An index of check node is induced, and then, there are two possibilities:

At the beginning of each coset, one of two possibilities is selected: colors {0, 1,2,3} or {4,5,6,7}. This will ensure compliance with problem goal (iii) above. In addition, following processes are performed in following conditions:

(i) A case where the check node that corresponds to the index is already accessed by the process and is already defined.

In this case, the number of those (variable nodes) that already have color is maximized and A_{mod(i+j·d,m)} to be a set 4 variable nodes of this check node is taken such that it maximizes the relevant norm of their degree.

(ii) a case where the check node that corresponds to the index is not yet accessed by the process.

In such a case, A_{mod(i+j·d,m)} is calculated by going through all the non-accessed check nodes and finding one that has a set 4 variable nodes such that it maximizes the number of the variable nodes that already have color and maximizes the relevant norm of their degree.

As an example, in modulo-8 coloring algorithm, it is assumed that d is odd and 8|M and (π,σ,f) may be determined so that f(aₙ)=mod(n,8).

Next, algorithm 3 will be described below.

Algorithm 3: removal of read-before-write violation

This algorithm takes a graph that is output by algorithm 2, and an assignment of variables to sectors. This algorithm is to eliminate read-before-write violations by reordering checks and their adjacent variable nodes, without violating the conditions of algorithm 2.

The algorithm 3 performs following processes.

1. Reordering check nodes

In the graph, the check nodes are rearranged. The new order minimizes the number of shared variable nodes between consecutive check nodes. Also, the variable nodes shared by three consecutive check nodes are minimized.

A property of the output of the algorithm 2 is that reordered check nodes do not disrupt the collision-avoidance ensured by that algorithm.

2. Reordering adjacencies to variable nodes

Within each check node, an order of adjacencies to variable nodes is rearranged in order to minimize read-before-write violations in each check node. For example, an adjacency to a variable node shared by two consecutive check nodes is moved to the beginning of the first check node and the end of the second check node. “Moving” denotes exchanging two adjacencies, in the ordered list of neighbors of the check node.

In order not to interrupt the collision-avoidance obtained by the algorithm 2, the rearrangement according to the algorithm 3 may exchange only between adjacencies to variable nodes which belong to the same sector.

3. Random Greedy Algorithm

In this algorithm, the following is repeated for a fixed number: A check node and two of its adjacencies to neighboring variable nodes are selected at random. If exchanging the adjacencies does not increase the number of read-before-write violations, and does not introduce memory-collisions, the change is allowed. Otherwise, it is rejected.

Next, a method of performing an LDPC decoding according to efficient scheduling in the LDPC decoder 130A shown in FIG. 7 by using the above described algorithms 1 through 3 will be described below.

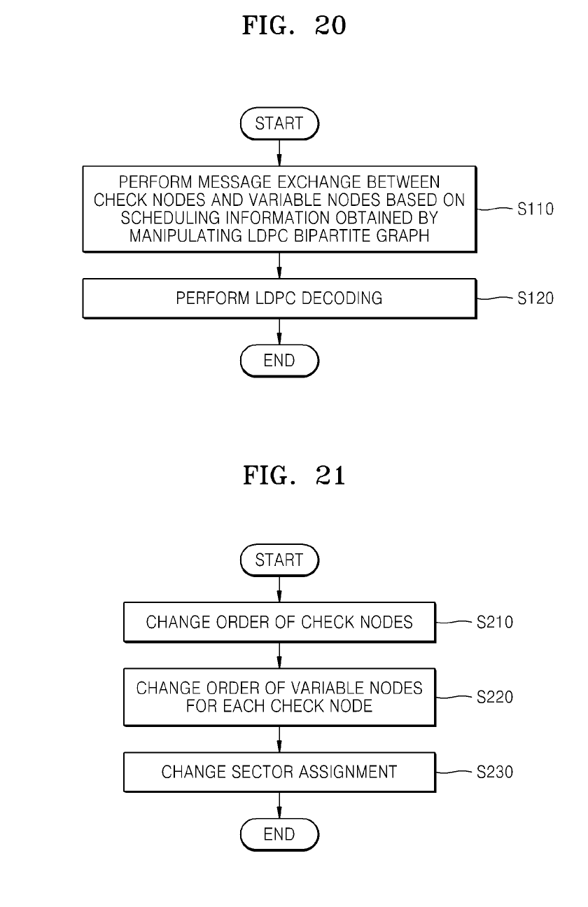

FIG. 20 is a flowchart illustrating an LDPC decoding method according to efficient scheduling according to an example embodiment of inventive concepts.

First, the control device 134 of the LDPC decoder 130A controls the logic device module 132 so that messages are exchanged between the check nodes and the variable nodes based on scheduling information obtained by manipulating an LDPC bipartite graph (S110). For example, the control device 134 may control the logic device module 132 so that messages are exchanged between the check nodes and the variable nodes in real-time based on scheduling information. Accordingly, reading or writing operation is performed to/from the first and second memories 131 and 133 based on the scheduling information. As described above, through the writing operation to the first memory 131 or the second memory 133, the variable node update or the check node update is performed.

The scheduling information may be determined by a processor by manipulating an order of the check nodes or an order of the variable nodes from the LDPC bipartite graph.

The scheduling information may be determined so that conditions for preventing the memory-access collisions and the read-before-write violations in the memory in which the states of the check nodes or the variable nodes are stored during the message exchange process between the check node and the variable node. Also, in order to reduce the routing congestion, each of 2P logic devices may be determined so that the number of sectors may be reduced as small as possible. In addition, in order to achieve memory efficiency (logic gates per memory bit), the memory sectors may be determined so that the number of variable nodes contained therein may be balanced. Such an operation for determining the scheduling information is performed off-line. Referring to FIG. 1, the scheduling information acquired by manipulating the LDPC bipartite graph off-line may be stored in the memory device 200.

Next, the control device 134 of the LDPC decoder 130A performs the LDPC decoding process based on the variable node update execution result according to the message exchange process of operation S110 (S120). That is, after performing a tentative decoding process based on the variable node update execution result, it is determined whether there is an error of the tentative decoding result. For example, the control device 134 may perform the LDPC decoding process in real-time based on the variable node update execution result according to the message exchange process.

For example, it may be determined whether there is an error based on a hard decision result of the states of the updated variable nodes. If it is determined that there is an error as a tentative decoding process, the check node update and the variable node update according to the message exchange are repeatedly performed. If it is determined whether there is no error as the tentative decoding result, the hard decision result of the states of the updated variable nodes is output as decoded data.

FIG. 21 is a flowchart illustrating a method of determining scheduling information according to an example embodiment of inventive concepts.

An operation of determining the schedule information is performed off-line. For example, the schedule information may be determined by a processor in a stage of developing products, and the determined scheduling information may be stored in the memory device 200 of FIG. 1.

In operation S210, reordering of the check nodes is performed in a list that represents the LDPC bipartite graph equivalently. For example, in the list shown in FIG. 11 representing the LDPC bipartite graph of FIG. 10 equivalently, left rows of column 1 and column 2 are exchanged, and then, the list shown in FIG. 15 may be obtained. This is the same as exchanging the names of the check node 1 and the check node 2.

In operation S220, reordering of the adjacent variable nodes connected to each of the check nodes is performed. For example, the orders of the variable nodes 1 and 5 may be exchanged in the list of adjacent variable nodes to the check node 0, in the list shown in FIG. 15. In addition, the variable nodes 5 and 7 adjacent to the check node 1 are exchanged, and pairs (4, 12) and (13, 14) of the adjacent variable nodes to the check node are exchanged. When reordering the variable nodes as above, the changed serial check list and the serial variable node list for each check node may be obtained.

In operation S230, changing of the sector assignment to the variable nodes is performed. For example, in the table of FIG. 13, in which the variable nodes are assigned to the memory sectors partitioned into six, when the variable node 5 is changed from the memory sector A to the memory sector B, the table shown in FIG. 17 may be obtained.

By performing the operations S210 through S230 repeatedly, the scheduling information by which the memory-access collisions and the read-before-write violations do not occur is found. The found scheduling information may be additionally manipulated to change the memory sector assignment to the variable nodes so as to reduce the routing congestion.

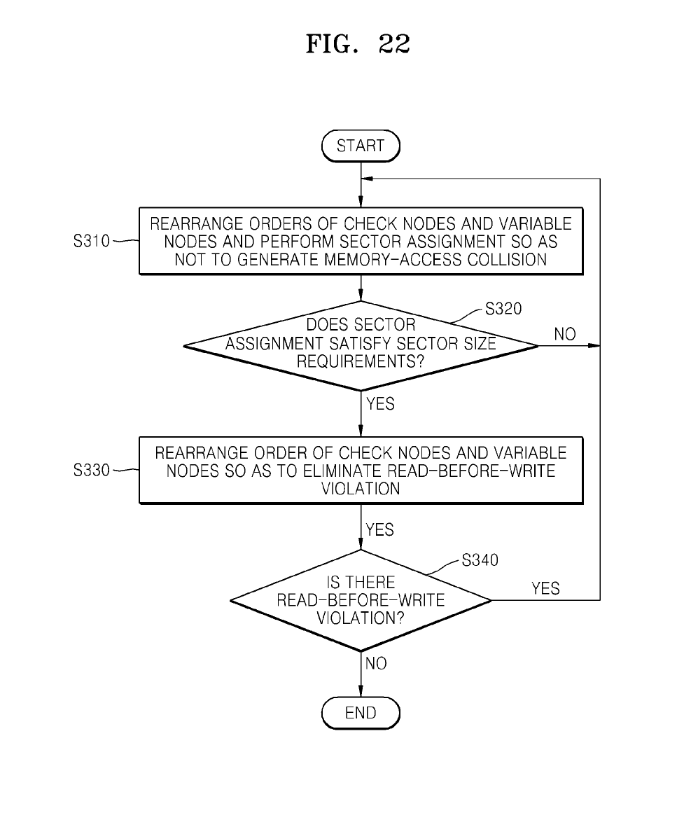

FIG. 22 is a flowchart illustrating a method of determining scheduling information according to another example embodiment of inventive concepts.

In operation S310, rearrangement of the orders of the check nodes and the variable nodes and the sector assignment are performed so as not to generate the memory-access collisions. For example, the sector assignment and the rearrangement of the check nodes and the variable nodes, which satisfy the conditions in which the memory-access collisions do not occur, may be found by applying the above described algorithm 2.

In operation S320, it is verified whether the sector assignment satisfies the sector size requirements. The sector size requirements may include, for example, a condition where the variable nodes included in each memory sector are contained in an allowable number that is set initially.

In a case where the sector assignment may not satisfy the sector size requirements as a result of determination in operation S320, the operation S310 starts again.

In operation S330, if the sector assignment satisfies the sector size requirements as a result of the determination in operation S320, the check nodes and the adjacent variable nodes to the check nodes are rearranged in order to eliminate the read-before-write violations. For example, the sector assignment and the rearrangement result of the check nodes and the variable nodes, which satisfy the condition by which the memory-access collisions do not occur, may be found by applying the above described algorithm 3.

In operation S340, it is evaluated whether there is the read-before-write violation in the rearrangement result of operation S320.

As a result of evaluation in operation S340, if there is the read-before-write violation, the operation S310 starts again.

If there is no read-before-write violation as a result of evaluation in the operation S340, the rearranged result in operation S330 is determined as final scheduling information.

The LDPC decoding method may be applied to various electronic devices, as well as the memory system. For example, the LDPC method may be applied to a wired communication system and a wireless communication system.

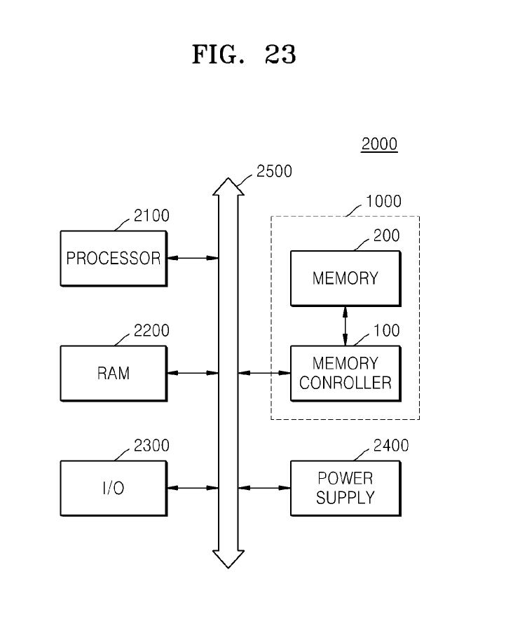

FIG. 23 is a block diagram of an electronic apparatus adopting a memory system according to an example embodiment of inventive concepts.

Referring to FIG. 23, an electronic apparatus 2000 includes a processor 210, a read-only-memory (RAM) 2200, an input/output device 2300, a power supply device 2400, and a memory system 1000. Although not shown in FIG. 23, the electronic apparatus 2000 may further include ports that may communicate with video cards, sound cards, or universal serial bus (USB) devices, or other electronic devices. The electronic device 2000 may be realized as a personal computer, or a portable electronic device such as a notebook computer, a mobile phone, a personal digital assistant (PDA), and a camera.

The memory system 1000 shown in FIG. 23 may be the memory system 1000A or 1000B shown in FIG. 1 or FIG. 2. Thus, data read from the memory device 200 may be decoded by using the LDPC decoding method according example embodiments.

The processor 2100 may perform certain calculations or tasks. Accordingly, the processor 2100 may be a microprocessor or a central processing unit (CPU). The processor 2100 may communicate with the RAM 2200, the input/output device 2300, and the memory system 1000 via a bus 2500 such as an address bus, a control bus, and a data bus. In some embodiments of the present inventive concept, the processor 2100 may be connected to an expanded bus such as peripheral component interconnect (PCI) bus.

The RAM 2200 may store data that is necessary to operate the electronic apparatus 2000. For example, the RAM 2200 may be a dynamic RAM (DRAM), a mobile DRAM, an SRAM, a PRAM, an FRAM, an RRAM, and/or an MRAM.

The input/output device 2300 may include an input unit such as a keyboard, a keypad, or a mouse, and an output unit such as a printer or a display. The power supply device 2400 may supply an operating voltage to operate the electronic apparatus 2000.

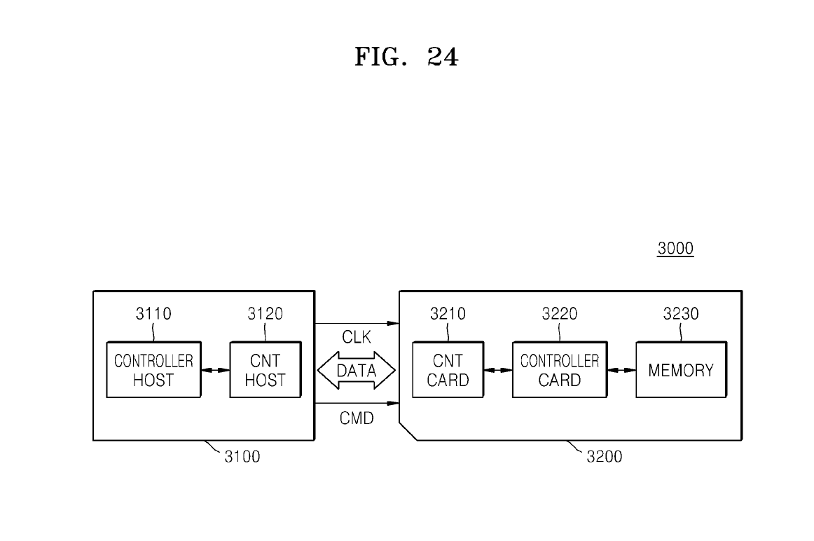

FIG. 24 is a block diagram of a memory card system including a memory system 3000 according to an example embodiment of inventive concepts.

Referring to FIG. 24, the memory card system 3000 may include a host 3100 and a memory card 3200. The host 3100 includes a host controller 3110, and a host connecting unit 3120. The memory card 3200 may include a card connecting unit 3210, a card controller 3220, and a memory device 3230.

The card controller 3220 and the memory device 3230 shown in FIG. 24 may be the memory controller 100 and the memory device 200 or 200′ shown in FIG. 1 or FIG. 2.

The host 3100 may write data to the memory card 3200, or may read data stored in the memory card 3200. The host controller 3110 may transmit commands CMD, clock signals CLK generated in a clock generator (not shown), and data DATA to the memory card 3200 via the host connecting unit 3120.

The card controller 3220 may perform a decoding operation of the data read from the memory device 3230 by using the LDPC decoding method according to inventive concepts, in response to the command received via the card connecting unit 3210.

The memory card 3200 may be a compact flash card (CFC), a microdrive, a smart media card (SMC), a multimedia card (MMC), a security digital card (SDC), a memory stick, or a US flash memory driver.

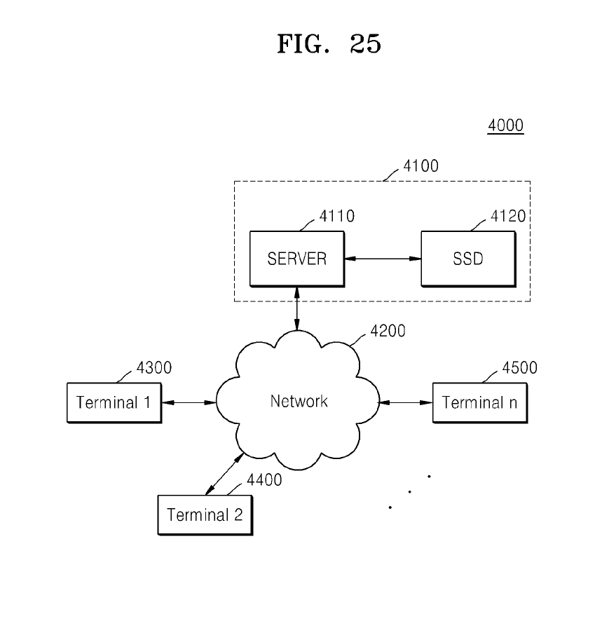

FIG. 25 is a block diagram showing an example of network configuration about a server system 4100 including an SSD according to an example embodiment of inventive concepts.

Referring to FIG. 25, the network system 4000 may include a server system 4100, and a plurality of terminals 4300, 4400, and 4500 connected to each other via a network 4200. The server system 4100 of the present embodiment may include a server 4110 processing requests transmitted from the plurality of terminals 4300, 4400, and 4500 connected to the network 4200, and an SSD 4120 storing data corresponding to the requests transmitted from the terminals 4300, 4400, and 4500. Here, the SSD 4120 may be the memory system 1000A or 1000B shown in FIG. 1 or FIG. 2.

Meanwhile, the memory system according to inventive concepts may be mounted by using various types of packages. For example, the memory system according to inventive concepts may be mounted by using packages such as a package on package (PoP), ball grid arrays(BGAs), chip scale packages(CSPs), plastic leaded chip carrier(PLCC), plastic dual in-line package(PDIP), die in waffle pack, die in wafer form, chip on board (COB), ceramic dual in-line package (CERDIIP), plastic metricquad flat pack (MQFP), thin quad flatpack (TQFP), small outline (SOIC), shrink small outline package (SSOP), thin small outline (TSOP), thin quad flatpack (TQFP), system in package (SIP), multi-chip package (MCP), wafer-level fabricated package (WFP), and wafer-level processed stack package (WSP).

While inventive concepts have been particularly shown and described with reference to example embodiments thereof, it will be understood that various changes in form and details may be made therein without departing from the spirit and scope of the following claims.

What is claimed is:

1. A low density parity check (LDPC) decoding method, the method comprising:
exchanging messages between check nodes and variable nodes based on scheduling information representing an order of exchanging messages between the check nodes and the variable nodes for an LDPC decoding; and
performing the LDPC decoding based on the exchanged messages,
wherein the scheduling information is determined by manipulating at least one of an order of the check nodes and an order of the variable nodes in an LDPC bipartite graph.

2. The LDPC decoding method of claim 1, wherein the order of the check nodes is manipulated and the manipulation of the order of the check nodes is performed by exchanging numbers of the check nodes in a serial-check list according to the LDPC bipartite graph.

3. The LDPC decoding method of claim 1, wherein the order of the variable nodes is manipulated and the manipulation of the order of the variable nodes is performed by reordering the variable nodes adjacent to each check node in a serial-check list according to the LDPC bipartite graph.

4. The LDPC decoding method of claim 2, wherein after the manipulation of the order of the check nodes, the scheduling information is obtained by reordering the variable nodes adjacent to each check node row in the serial-check list.

5. The LDPC decoding method of claim 1, wherein the scheduling information includes information about an order of exchanging the messages between the check nodes and the variable nodes.

6. The LDPC decoding method of claim 1, wherein the scheduling information prevents memory-access collisions in memory storing states of the variable nodes during the exchanging.

7. The LDPC decoding method of claim 1, wherein the scheduling information prevents read-before-write violations during the exchanging.

8. The LDPC decoding method of claim 1, wherein the scheduling information prevents memory-access collision and read-before-write violations in memory storing states of the variable nodes during the exchanging.

9. The LDPC decoding method of claim 1, wherein the scheduling information includes information about a block-serial-check scheduling, and the block-serial-check scheduling permitting states of a plurality of the variable nodes in a same block to be accessed in parallel in one clock cycle.

10. The LDPC decoding method of claim 1, wherein the scheduling information is determined by manipulating the order of the check nodes and the order of the variable nodes in the LDPC bipartite graph.

11. The LDPC decoding method of claim 1, wherein the states of the variable nodes are stored separately in a plurality of memory sectors that are partitioned.

12. The LDPC decoding method of claim 1, wherein the scheduling information is LDPC schedule table information including a serial-check list and a serial-variable list for each check node, wherein the LDPC schedule table information is found by repeatedly performing a process of exchanging numbers of the check nodes in the serial-check list and a process of reordering the variable nodes in the serial-variable list of each check node.

13. A method of determining scheduling information for decoding, the method comprising:
determining an order of check nodes for processing at a first memory;
determining an order of variable nodes for each check node for processing at a second memory;
assigning a number of sectors in the second memory to the variable nodes, the number of sectors being based on a parallelization factor, the parallelization factor representing a first number of the variable nodes that are read in one cycle and a second number of the variable nodes that are written in the one clock cycle;
determining sector assignments for the variable nodes, respectively; and
generating the scheduling information based on the sector assignments.

14. The method of claim 13, wherein the number of sectors is two times the parallelization factor.

15. The method of claim 13, further comprising:
determining a number of logic devices to process the check nodes and variable nodes, the number of logic devices being less than the number of sectors.
